(19) United States
(12) Patent Application Publication
(10) Pub. No.: US 2013/0284248 A1
(43) Pub. Date: Oct. 31, 2013

(54) SOLAR CELL HAVING THREE DIMENSIONAL JUNCTIONS AND A METHOD OF FORMING THE SAME

(71) Applicants: Solanki Chetan Singh, Mumbai (IN); Som Mondal, West Bengal (IN)

(72) Inventors: Solanki Chetan Singh, Mumbai (IN); Som Mondal, West Bengal (IN)

(73) Assignee: INDIAN INSTITUTE OF TECHNOLOGY, BOMBAY, Mumbai, Maharashtra (IN)

(21) Appl. No.: 13/996,672

(22) PCT Filed: Dec. 20, 2011
(86) PCT No.: PCT/IN11/00880

§ 371 Date: Jun. 21, 2013

(30) Foreign Application Priority Data
Dec. 21, 2010 (IN) 3467/MUM/2010

(51) Int. Cl. H01L 31/0236

(52) U.S. Cl. CPC H01L 31/02363
USPC 136/255; 438/71

(57) ABSTRACT

A method of forming a solar cell 100 having three dimensional junctions 116 created between a conductive substrate 102 having a first conductivity and a conductive layer 120 having an opposite second conductivity comprising the steps of applying the conductive layer 120 on a top surface 104 of the conductive substrate 102, exposing selective portions of the conductive layer 102 to laser radiations 124 having a wavelength ranging up to 10.6 μm. Due to this laser application, the conductive layer 102 diffuses across a thickness of the conductive substrate 102 in the form of a plurality of channels 126. The plurality of channels 126 being formed in spaced apart relationship with each other. Thereafter, metal contacts are thermosetted on a bottom surface 114 of the conductive substrate 102 for electrically connecting exposed ends 136 of the plurality of channels 126.

### FIELD OF THE INVENTION

The present invention relates to solar cells and more particularly, to solar cells having three dimensional junctions formed between materials of different conductivities.

### DESCRIPTION OF THE BACKGROUND ART

Photovoltaic devices, such as silicon solar cells, are useful for converting solar energy into electrical energy. In order for photovoltaic devices to be economically feasible and be used by the general public, it is advantageous to utilize methods that are efficient and practical. There are literally hundreds of methods and inventions relating to various manufacturing techniques attempting to achieve efficiency. However, solar cells are complex systems and embody a myriad of parameters in their fabrication. One of the important parameters is the amount of active area of the solar cell device which is exposed to the solar energy, especially for large area solar cells. Electrical connections necessary for the operation of the device block the transmission of solar energy into the active portions of the solar cell. This leads to losses commonly known as front contact shadow losses.

The electrical connections are generally opaque in nature are positioned on top of the active semiconductor material facing the incident solar energy. To reduce active area loss, it is advantageous to minimize the area blocked by these electrical connections. Further, it is also advantageous to produce electrical connections which can be manufactured quickly, inexpensively, and efficiently. Furthermore, the resultant electrical connections must have a sufficiently low resistance to conduct electricity through the cell. However, the problem associated with thinning the wires or grids used as electrical connections is increase in resistance of the thinner wires than in a thicker connection. Generally, minimizing the size of an electrical connection increases i²R losses due to the increase in the resistance of the connection. Another associated drawback is the quality of electrical contact at the interface with the conventional laser-scribing approach.

The above mentioned problems, however, are addressed up to certain extent by the design of the Metal-Wrap-Through (MWT) solar cells. The MWT technology, among addressing other drawbacks, is basically aimed at reducing the front contact shadow losses observed within the solar cells. In such practice, the bus bars that are used for carrying the charge carriers to an external load are formed at the bottom of the solar cell, instead of top. This is done by either wrapping a conductor around sides of the solar cell or by drilling holes across the thickness of the solar cell. The conductor passes through the drilled hole in between the front surface to the rear surface of the solar cell so that the electrical contacts can be shifted from the front surface to the rear surface. Generally, drilling of holes is done either by laser or by some mechanical means known in the art. However, there are certain drawbacks associated with the MWT technology as well. First, it has been experimentally observed in such solar cells that the reduction in shadow loss in only up to 2-3% and therefore, the problem of shadow loss is only partly addressed by this technology. Second, the induced thermal stress during drilling of holes by laser or mechanical means reduces the life of such solar cells. Third, during said drilling process the silicon is removed in bulk thereby severely limiting the free positive charge carrier separation/collection.

Thus, there is a need for fabricating solar cells that at least addresses some of the above noted drawbacks.

### SUMMARY OF THE INVENTION

Disclosed herein is a method of forming a solar cell having three dimensional junctions created between a conductive substrate having a first conductivity and a conductive layer having a second conductivity, the first and the second conductivities being opposite to each other in polarity, the method including the steps of applying the conductive layer on a top surface of the conductive substrate, exposing selective portions of the conductive layer to laser radiations having a wavelength ranging up to 10.6 μm so as to diffuse the conductive layer across a thickness of the conductive substrate, the conductive layer being diffused in the form of a plurality of channels formed in spaced apart relationship with each other, thermosetting metal contacts on a bottom surface of the conductive substrate for electrically connecting exposed ends of the plurality of channels.

In some embodiments, prior to applying laser radiations on the top surface of the conductive substrate, uniformly doping the conductive layer of second conductivity at least on the bottom surface of the conductive substrate, and upon laser application diffusing ends of the channels opening up in the conductive layer applied on the bottom surface.

In some embodiments, post laser diffusion, uniformly applying a layer of an antireflective coating on the top surface and a passivation layer on the bottom surface of the conductive substrate.

In some embodiments, etching selective portions of the antireflective coating applied on the bottom surface in a manner to first, expose ends of each of the channels and second, to expose selective portions of the conductive layer, each of the selectively exposed portions being located at a distance from the exposed ends of the channel, and wherein disposing a metallic material having the first conductivity on each of the selectively exposed portions of the conductive layer.

In some embodiments, thermosetting the metallic material so as to partially diffuse the metallic material within the conductive layer and the conductive substrate lying immediate to the conductive layer.

According to another aspect of the present invention, a solar cell having three dimensional junctions formed between a conductive substrate having a first conductivity and a conductive layer having a second conductivity, the first and the second conductivities being opposite to each other in polarity, the solar cell including a plurality of conductive substrate having the first conductivity formed by laser diffusing the conductive layer having the second conductivity in a predetermined manner to form three dimensional junctions between the plurality of conductive substrate and the conductive layer, the three dimensional junctions extending in x, y, and z dimensions, the x and y dimensions extending along a width of the solar cell, and a plurality of corresponding metal contacts formed at the end of the z-dimension of the three dimensional joints.

In some embodiments, a top surface of the solar cell has a layer of the conductive layer applied thereon and selective portions of the conductive layer being laser diffused across thickness of the solar cell in the form of a plurality of channels, the plurality of channels being disposed in spaced apart relationship with each other.

In another embodiment, the conductive layer of second conductivity being disposed on a bottom surface of the solar cell, ends of each of the channels opening in the conductive layer and exposing out from the bottom surface.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description of the present embodiments of the invention are intended to provide an overview or framework for understanding the nature and character of the invention as it is claimed. The accompanying drawings are included to provide a further understanding of the invention and are incorporated into and constitute a part of this specification. The drawings illustrate various embodiments of the invention and together with the description serve to explain the principles and operation of the invention.

### A BRIEF DESCRIPTION OF THE DRAWINGS

The above-mentioned and other features and advantages of the various embodiments of the invention, and the manner of attaining them, will become more apparent will be better understood by reference to the accompanying drawings, wherein:

FIGS. 1-12 illustrate a method of forming a solar cell having three dimensional junctions formed between a conductive substrate and a conductive layer of different conductivities, according to an embodiment of the present invention;

FIG. 13 shows a perspective elevational view of a solar cell formed according to methods shown in FIGS. 1-12.

### DETAILED DESCRIPTION OF THE PREFERRED EMBODIMENTS

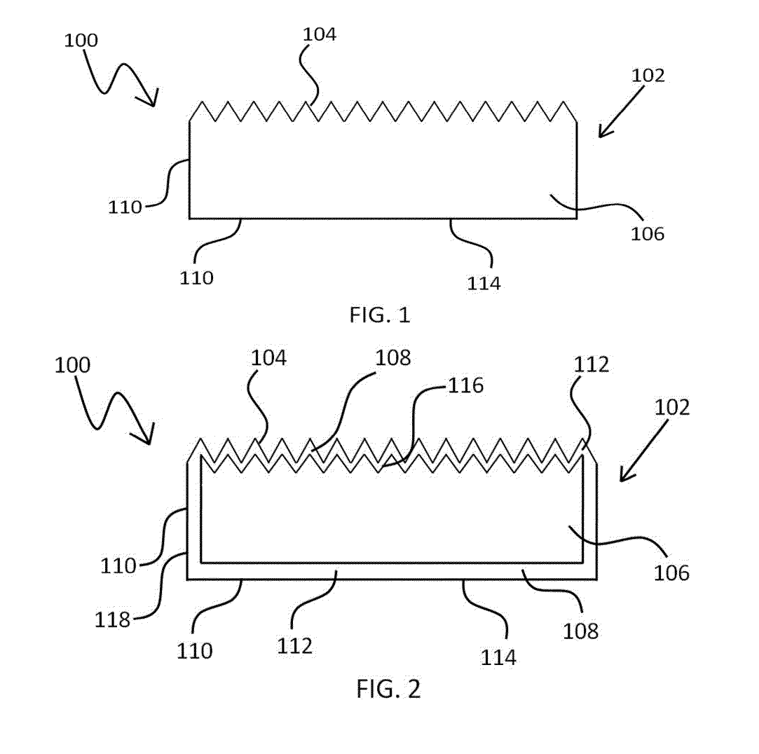

FIGS. 1-12 show a method of formation of a solar cell 100 according to an embodiment of the present invention. As shown in FIG. 1, a conductive substrate 102 having a sufficient thickness is taken and chemically treated by processes described below in the following description for the formation of the solar cell 100. Preferably, a top surface 104 of the conductive substrate 102 is shown to be textured however, other surfaces of the conductive substrate 102 may also be textured by chemical treatment as explained below. Preferably, the conductive substrate 102 is formed by doping a silicon (Si) crystalline structure 106 with a p-type charge carrier material such as Boron (not shown), which has abundance of positive free charge carriers, in known manner. For the purposes of explaining various embodiments of the present invention, the positive free charge carriers present within the conductive substrate 102 will be referred to as the conductive substrate 102 having a first conductivity. Further, various other combinations of materials may also be chosen for the formation of conductive materials having the first conductivity and considered to be within the scope of the present invention.

As shown in FIG. 2, the conductive substrate 102 having the first conductivity is heavily doped with an n-type charge carrier material 108. Preferably, compositions of Phosphorous/Arsenic having abundance of negative free charge carriers is doped within the conductive substrate 102 from all the six sides 110 of the conductive substrate 102. Preferably, Phosphorous/Arsenic is doped in a controlled gaseous environment and at temperature range of 900° C.-1400° C. As such, the n-type charge carrier material 108 diffuses within the conductive substrate 102 from all the six sides 110. As a result of this diffusion, Phosphorous/Arsenic occupies a thick layer 112 on all the six sides 110 of the conductive substrate 102 including the top surface 104 and a bottom surface 114 (See FIG. 2).

Further, this doping also forms a two-dimensional p-n junction 116 between the Phosphorous/Arsenic doped thick layer 112 and the conductive substrate 102 and positioned adjacent to all of the six sides 110 of the conductor substrate (FIG. 2). The p-n junctions 116, as well known in the semi-conductor art, are the portion of the solar cell 100 (semiconductor) where there is higher possibility of separation between the positive and negative charge carriers. Preferably, parameters of doping are chosen such that the thickness of the Phosphorous/Arsenic doped thick layer 112 present on the top surface 104 and on the bottom surface 114 of the conductive substrate 102 is within (0.05 to 1) μm range. In one embodiment, only the top and the bottom surfaces 104, 114 of the conductive substrate 102 may be doped with Phosphorous/Arsenic without doping the other four sides 110 of thereof. In another embodiment, instead of doping within the gaseous environment, other techniques known in the art may also be used. All these embodiments should be considered to be within the scope of the present invention. For the purposes of explaining various embodiments of the present invention in the foregoing description, the negative charge carriers present within the Phosphorous/Arsenic doped thick layer 112 and doped within the conductive substrate 102 will be referred to be having a second conductivity. The thick layer 112 of the Phosphorous/Arsenic doped on the top surface 104 of the conductive substrate 102 acts as a front emitter for the solar cell 100 when in operation. Furthermore, the p-n junction 116 formed between the Phosphorous/Arsenic doped thick layer 112 and the conductive substrate 102 near the top surface 104 thereof will be only referred in following description.

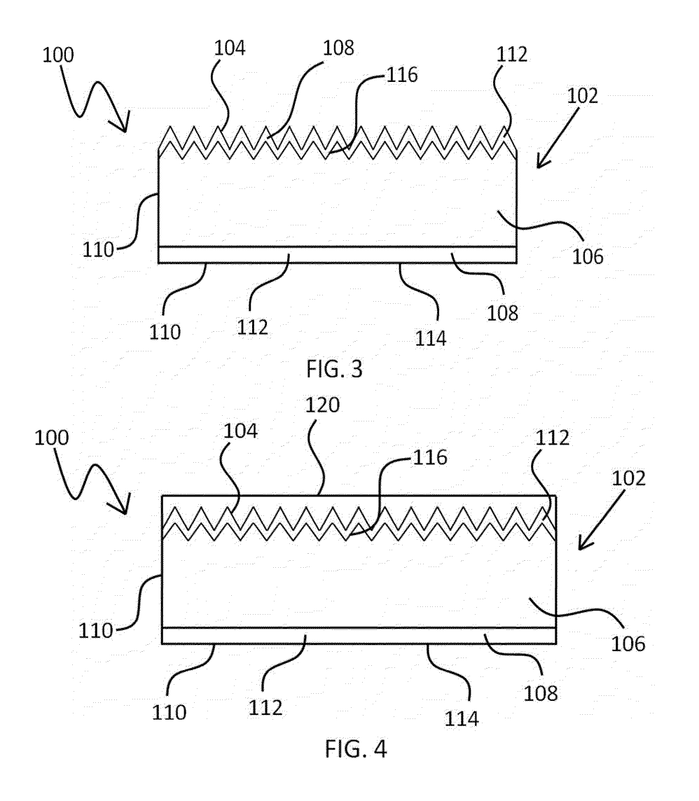

Post doping of Phosphorous/Arsenic, edge isolation of the edges 118 of the doped conductive substrate 102 is performed. This is done by removing the Phosphorous/Arsenic doped thick layer 112 from the four sides 110 of the doped conductive substrate 102 except from the top surface 104 and the bottom surface 114 (FIG. 3). Preferably, techniques such as plasma etching and laser ablation may be used for removing the doped Phosphorous/Arsenic. However, other techniques known the art may also be used considered to be within the scope of the present invention.

As shown in FIG. 4, a layer of n-type charge carrier material 120 having the second conductivity is applied on the top surface 104 of the doped conductive substrate 102. Preferably, a source layer containing Phosphorous atoms is used as the n-type charge carrier material 120 and applied uniformly over Phosphorous/Arsenic doped thick layer 112 are present. In various embodiments, other compositions of n-type charge carrier material 120 may also be applied on the Phosphorous/Arsenic doped thick layer 112 and considered to be within the scope of the present invention. For the purposes of explaining various embodiments of the present invention, the applied Phopho silicate glass composition will be referred to as a conductive layer 120 having the second conductivity.

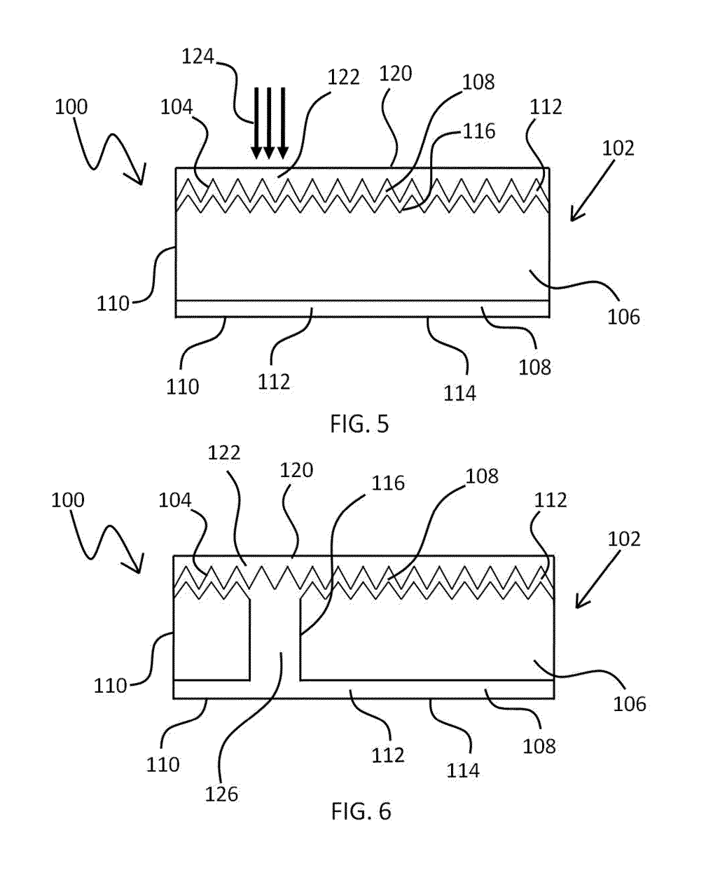

As shown in FIG. 5, post application of the conductive layer 120 on the doped conductive substrate 102, selective portions 122 of the conductive layer 120 is subjected to application of laser radiations 124 from a laser power source (not shown). Preferably, the laser radiations 124 for exposing selective portions 122 have a wavelength ranging up to 10.6 μm and are exposed for a sufficient time. In order to achieve these parameters of laser exposure, the power intensity of the laser radiations 124 is controlled accordingly. This ensures that during laser exposure portions 122 of the conductive substrate 102 are not ablated or removed.

Once the exposure of the laser radiations 124 starts at selective portions 122, the conductive layer 120 present there starts diffusing within the Phosphorous/Arsenic doped thick layer 112 as well as within the conductive substrate 102. As the exposure continues, the conductive layer 120 starts sinking across the thickness of the conductive substrate 102 towards the Phosphorous/Arsenic doped thick layer 112 present on the bottom surface 114 of the conductive substrate 102. Further, due to this diffusion, the two dimensional p-n junctions 116 is deformed and are pushed towards the bottom surface 114 of the doped conductive substrate 102 in a shape of plurality of distinct channels 126. This also results in the two dimensional p-n junction 116 between the conductive substrate 102 and the conductive layer 120 being transformed into a plurality of three dimensional p-n junction 116. As the conductive layer 120 diffuses further towards the bottom surface 114 of the conductive substrate 102, formation of the channels 126, and accordingly the three dimensional p-n junctions 116, continues until each of the channels 126 open up in the Phosphorous/Arsenic doped thick layer 112 present on the bottom surface 114 of the doped conductive substrate 102. Thus, each of the channels 126 extends between the top surface 104 and the bottom surface 114 of the conductive substrate 102.

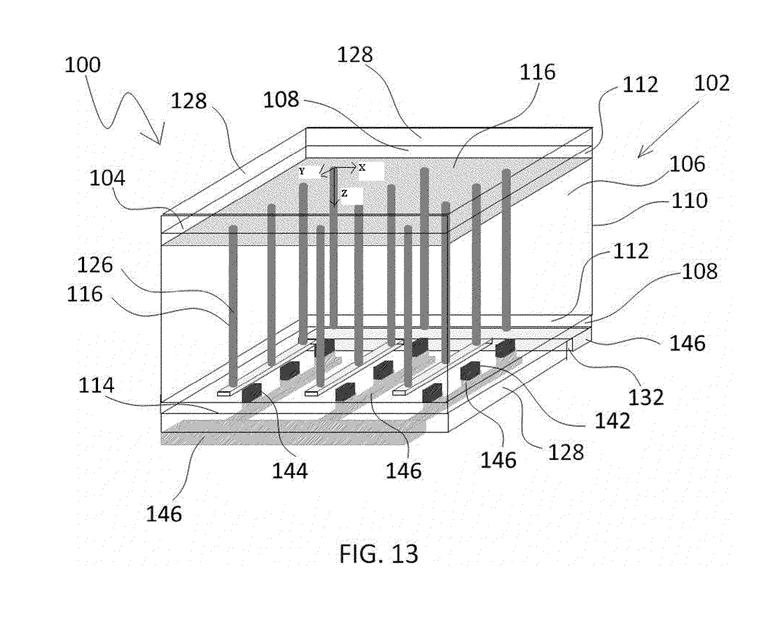

After the formation of the plurality of channels 126, the laser power source is turned off. Further, it will also be understood that the plurality of channels 126 ranges up to thousands within the doped conductive substrate 102. Preferably, the plurality of channels 126 is arranged linearly in plurality of parallely spaced lines within the doped conductive substrate 102 with each of the lines having an equal number of the channels 126 (See FIG. 13). As such, the charge separation capability of the solar cell 100 is dramatically increased. The channel 126 formed across the thickness of the conductive substrate 102 due to the laser diffusion is seen in FIG. 6. There are two associated characteristics along with the formed channel 126. First, during solar cell 100 operation, the free charge carriers from the Phosphorous/Arsenic doped thick layer 112 would travel through this channel 126 and may be collected at the bottom. Second, instead of a single two dimensional p-n junction 116 formed along the length and width of the conductive substrate 102, a three dimensional p-n junction 116 is formed along length, the width, and the thickness of the conductive substrate 102.

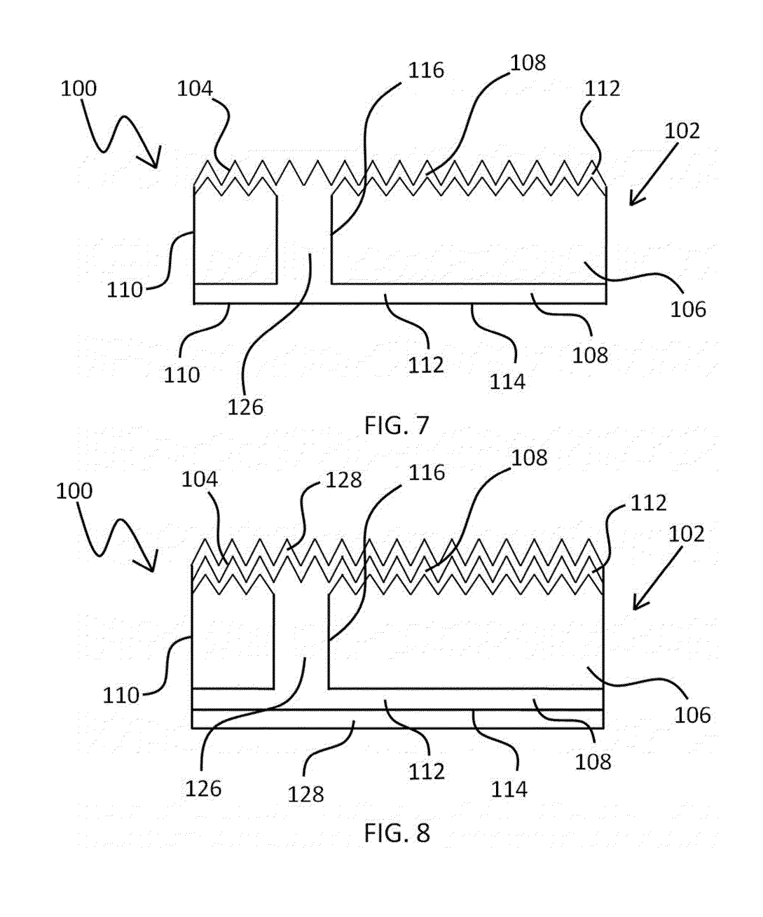

Once the plurality of channels 126 is formed and the laser supply source turned off, portions of the conductive layer 120 remaining on top of the Phosphorous/Arsenic doped thick layer 112 is removed. This is done by chemically treating the conductive layer 120 with alcohol and hydrochloric acid. The solar cell 100 obtained after this chemical treatment is shown in FIG. 7. A layer of Silicon Nitride (SiNx) material, which acts as an anti-reflective coating, is applied on the top surface 104 and a layer of Al₂O₃/SiNₓ that acts as a passivation layer 128 is applied on the bottom surface 114 of the conductive substrate 102. Preferably, the passivation layer 128 is deposited by chemical vaporization technique, which is a well known in the art. The passivation layer 128 is applied in such a manner that the Phosphorous/Arsenic doped thick layer 112 material that is present on the top and bottom surfaces 104, 114 of the conductive substrate 102 is fully covered (FIG. 8). A benefit of applying the passivation layer 128 is that the passivation layer 128 acts as an antireflective coating for the incident solar energy. Another benefit of applying the passivation layer 128 is that it prevents recombination of charge carriers within the solar cell 100. In one embodiment of the present invention, the passivation layer 128 may be applied only on the top and the bottom surfaces 104, 114 of the conductive substrate 102. In several other embodiments, the passivation layer 128 may also be applied on some or all of the remaining sides 110 of the solar cell 100 that may or may not have the Phosphorous/Arsenic doped thick layer 112 material therein.

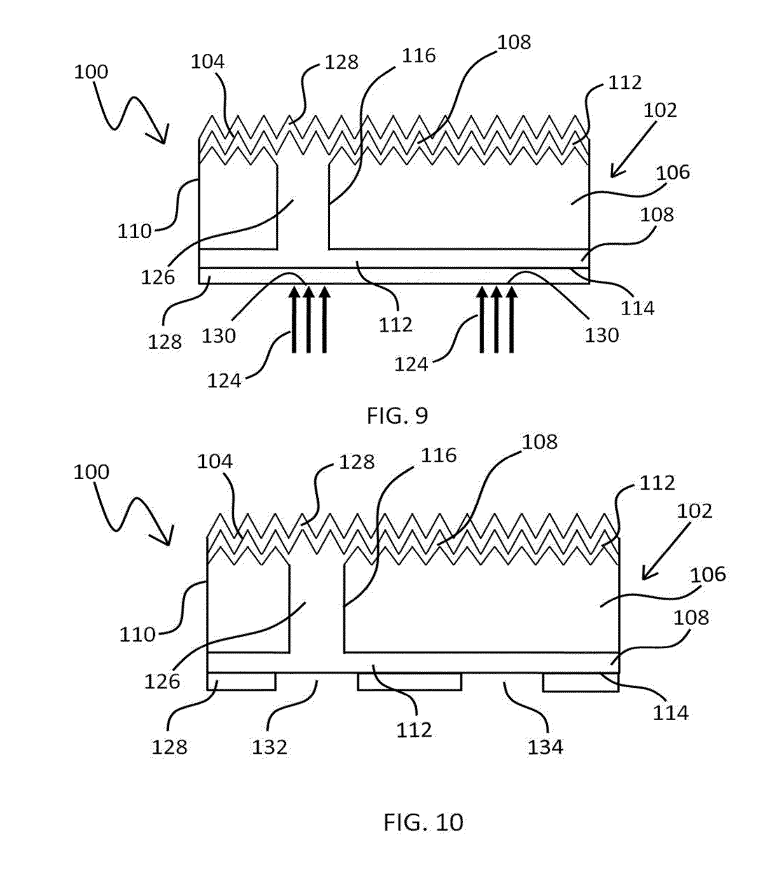

Once the passivation layer 128 is applied on the bottom of the solar cell 100, selective portions 130 of the passivation layer 128 applied on the bottom surface 114 of the solar cell 100 is subjected to application of laser radiations 124 (See FIG. 9). The chosen selective portions 130 of the passivation layer 128 are etched to expose corresponding portions of the conductive layer 120 present adjacent to each of the zone of laser application. Preferably, etching is done in a manner to form a plurality of a first pathway 132 and a plurality of a second pathway 134. Each of the first pathways 132 connects the exposed ends 136 of all the channels 126 linearly arranged in the corresponding single line, whereas each of the second pathways 134 is formed adjacent to the each of the first pathway 132. Preferably, a first common guideway 138 and a second common guideway 140 (See FIG. 13) is also formed by laser etching the passivation layer 128 so as to connect each of the first and the second pathways 132, 134, respectively. A cut-sectional view of the solar cell 100 having at least one of each of the first and the second pathways 132, 134 formed therein is illustrated in FIG. 10.

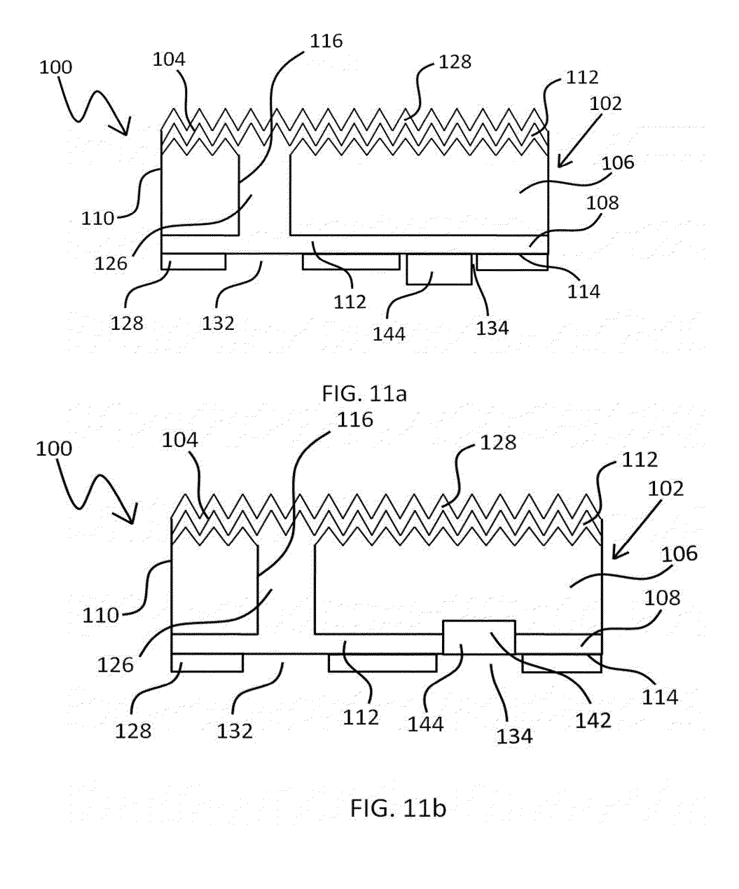

After formation of the pluralities of first and the second pathways 132, 134 on the bottom surface 114 of the solar cell 100, process of formation of plurality of heavily doped region 142 (BSF—Back Surface Film) within the conductive substrate 102 takes place. As shown in FIG. 11a, a metallic layer 144 is deposited at selective locations within one or more of the second pathways 134. Preferably, the metallic layer 144 chosen for deposition on the second pathway 134 is Aluminium (Al). The metallic layer 144 of this type is rich of positive free charge carriers and therefore, the conductivity of the metallic layer 144 is same as that of the conductive substrate 102, i.e. first conductivity. Preferably, for deposition of metallic layer 144 within the second pathway 134(s), the metallic layer 144 may be deposited by any one of the known techniques such as vacuum evaporation, screen printing, ink jet printing, etc. Once the metallic layer 144 is deposited within the second pathway 134, the metallic layer 144 is subjected to firing/annealing at a temperature of 700° C.-800° C. Once the firing starts, the metallic layer 144 starts diffusing within the conductive layer 120 having the second conductivity. On attaining the temperature of 700° C.-800° C., the metallic layer 144 is partially diffused both within the conductive layer 120 and the conductive substrate 102 with portions of the metallic material positioned within the second pathway 134 (FIG. 11b). As the metallic layer 144 is chosen to have the first conductivity, when diffused within the conductive substrate 102, the heavily doped region 142 of first conductivity is formed. Further, formation of the BSF region 142 also allows free positive charge carriers, which are present within the conductive substrate 102, to be taken outside from the solar cell 100 when connected with a metal contact. It will also be understood by a skilled person that a similar heavily doped region 142 will also be formed within each of the second pathways 134.

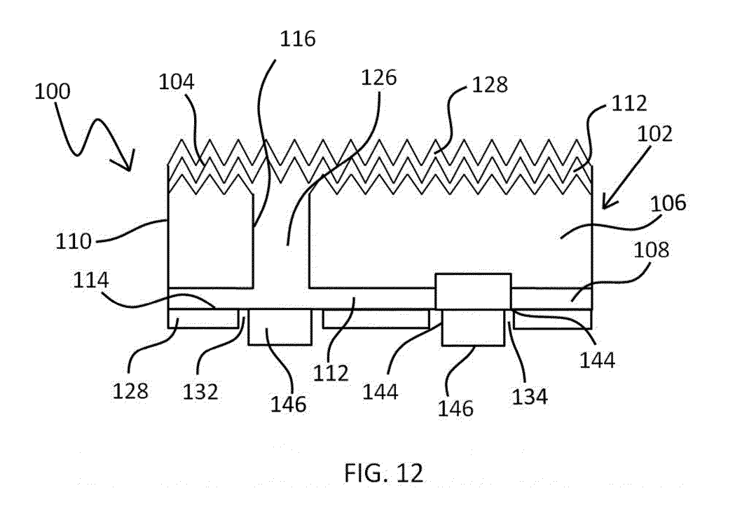

Post BSF 142 formation, as seen in FIG. 12, metallic contacts 146 are deposited within each of the first and second plurality of pathways 132, 134 for forming electrical contact with each of the conductive channels 126 and the BSF region 142, respectively. Preferably, a silver paste is chosen for forming metallic contacts 146. Finally, these respective metallic contacts 146 are electrically connected to an external load (not shown). During operation, when the solar cell 100 is exposed to the solar energy the free negative charge carriers generated within the Phosphorous/Arsenic doped thick layer 112 and the conductive layer 120 reaches the bottom of the solar cell 100 the plurality of the channels 126. These free negative charge carriers are received at the metallic contacts 146 and may be transferred to an external load. The free positive charge carriers generated within the conductive substrate 102 and within conductive layer is received at the metallic contacts 146 through the BSF region 142 and may be transferred to an external load. Both the free positive and negative charge carriers are finally taken outside from the solar cell 100 via the first common guideway 138 and the second common guideway 140.

The above mentioned embodiments provide quite a few solutions to the problems associated with the known solar cells, which will be appreciated by a skilled person in the art. First, as there are no contact fingers present on the top of the solar cell 100, all of the free negative charge carriers may be collected at the bottom if the solar cell 100. Thus, the persistent problem of shadow losses is nearly eliminated from this solar cell 100. Second, due to formation of more p-n junctions 116 within the solar cell 100, the charge separation and collection capability increases. As such, the overall efficiency of the solar increases. Third, due to the fact that the channels 126 are formed as a result of diffusion and not laser/mechanical drilling, as noted in known devices, mechanical strength of the solar cell 100 is not compromised. As a result of this greater mechanical strength, the overall life of the solar cell 100 increases. Fourth, the top surface 104 of the solar cell 100 being free from contact gives a better front surface passivation which reduces recombination and enhances cell efficiency. Additionally, the process does not include too many steps as compared to the conventional cell fabrication scheme and therefore, the implementation of such solar cell 100 is easier.

FIG. 13 shows a perspective view of the solar cell that is formed by the methods explained above with respect to the above embodiments. The solar cell is preferably formed by the cubical conductive substrate 102 having doped therein the n-type material 108 (Phosphorous/Arsenic). The n-type material 108 is preferably doped on top surface 104 and bottom surface 114 of the conductive substrate 102. Preferably, on top of the Phosphorous/Arsenic deposited within the conductive substrate 102, the conductive layer 120 (preferably of Phospho Silicate Glass) is applied. Conductivity of the conductive layer 120 is same as that of conductivity of the Phosphorous/Arsenic doped thick layer 112. Conductivity of the conductive substrate 102 would be referred to as the first conductivity (having free positive charge carriers therein) whereas conductivity of the conductive layer 120 would be referred to as the second conductivity (having free negative charge carriers therein). As understood, the first and the second conductivities are opposite to each other in polarity.

Portions of the conductive layer 120 present on top of the Phosphorous/Arsenic doped thick layer 112 is selectively subjected to laser radiations' 124 exposure having a wavelength in the range of (1030-1070) nm and for approximately 30 seconds. Due to this selective exposure, the conductive layer 120 having the first conductivity is laser diffused within the conductive substrate 102 crossing the Phosphorous/Arsenic doped thick layer 112 in the form of plurality of spaced apart channels 126. The plurality of channels 126 is formed between the doped Phosphorous/Arsenic present on the top surface 104 and the bottom surface 114 of the solar cell 100. Ends 136 of each of the channels 126 open up into the Phosphorous/Arsenic doped thick layer 112 doped at the bottom of the conductive substrate 102. As shown in the perspective view, each of the channels 126 lead to formation of a corresponding three dimensional junction 116 formed between the conductive substrate 102 and the conductive layer 120. Further, due to formation of the plurality of channels 126, the conductive substrate 102 of the solar cell 100 is being divided into a plurality of closely spaced conductive substrate 102.

As seen in FIG. 13, each of the channels 126 defining the three dimensional junction 116 extend in x, y, and z dimensions within the solar cell 100. The x and y dimensions extend along a length and a width, respectively, of the solar cell 100 whereas, the z-dimension extends along the thickness of the conductive substrate 102 and the solar cell 100. It would be appreciated by a skilled person in the art that there would be ‘n’ number (preferably thousand) of similar channels 126 formed within the solar cell 100 spanning throughout the length, width, and thickness of the conductive substrate 102. As a result, the charge separation probability is tremendously increased within the solar cell 100 leading to increase in overall efficiency of the solar cell 100 when in operation. Further, a plurality of corresponding metallic contacts 146 formed at the end of the z-dimension of the three dimensional junctions 116 that may be connected to an outside load (not shown).

The metallic contact 146 that is preferably formed of a silver material is deposited on the bottom surface 114 of the solar cell 100 in such a manner that it connects each of the exposed ends 136 of the plurality of channels 126. Preferably, as shown in FIG. 13, there is a plurality of lines of metallic contact 146 formed that electrically connects each of the exposed ends 136 of the plurality of channels 126 with an external load. During operation of the solar cell 100, the free negative charge carriers from the conductive layer 120 are transported to the metallic contacts 146 through the plurality of channels 126. Adjacent to the metallic contacts 146 connecting the channels 126, there is also formed plurality of other metallic contacts 146, preferably made from silver, to connect selective portions of the conductive substrate 102. As noted above in the method embodiments, in order to connect the conductive substrate 102 with the metallic contacts 146, a plurality of corresponding BSF regions 142 are formed. Additionally, the passivation layer 128 is also formed on the top surface 104 as well as on the non-metallic portions on the bottom surface 114 of the solar cell 100 for performing known functions.

It will be apparent to those skilled in the art that various modifications and variations can be made to the present invention without departing from the spirit and scope of the invention. Thus it is intended that the present invention cover the modifications and variations of this invention provided they come within the scope of the appended claims and their equivalents.

1. A method of forming a solar cell having three dimensional junctions created between a conductive substrate having a first conductivity and a conductive layer having a second conductivity, the first and the second conductivities being opposite to each other in polarity, the method comprising the steps of:
applying the conductive layer on a top surface of the conductive substrate;
exposing selective portions of the conductive layer to laser radiations having a wavelength ranging up to 10.6 μm so as to diffuse the conductive layer across a thickness of the conductive substrate, the conductive layer being diffused in the form of a plurality of channels formed in spaced apart relationship with each other;
thermosetting metal contacts on a bottom surface of the conductive substrate for electrically connecting exposed ends of the plurality of channels.

2. The method of forming a solar cell according to claim 1, wherein prior to applying laser radiations on the top surface of the conductive substrate, uniformly doping the conductive layer of second conductivity at least on the bottom surface of the conductive substrate, and upon laser application diffusing ends of the channels opening up in the conductive layer applied on the bottom surface.

3. The method of forming a solar cell according to claim 2, wherein post laser diffusion, uniformly applying a layer of an antireflective coating on the top surface and a passivation layer on the bottom surface of the conductive substrate.

4. The method of forming a solar cell according to claim 3, wherein etching selective portions of the antireflective coating applied on the bottom surface in a manner to first, expose ends of each of the channels and second, to expose selective portions of the conductive layer, each of the selectively exposed portions being located at a distance from the exposed ends of the channel, and wherein disposing a metallic material having the first conductivity on each of the selectively exposed portions of the conductive layer.

5. The method of forming a solar cell according to claim 4, wherein thermosetting the metallic material so as to partially diffuse the metallic material within the conductive layer and the conductive substrate lying immediate to the conductive layer.

6. The method of forming a solar cell according to claim 4, wherein thermosetting the metal contacts on each of the metallic material for electrically connecting the partially diffused metallic material with an external load.

7. A solar cell having three dimensional junctions formed between a conductive substrate having a first conductivity and a conductive layer having a second conductivity, the first and the second conductivities being opposite to each other in polarity, the solar cell comprising:
a plurality of conductive substrate having the first conductivity formed by laser diffusing the conductive layer having the second conductivity in a predetermined manner to form three dimensional junctions between the plurality of conductive substrate and the conductive layer, the three dimensional junctions extending in x, y, and z dimensions, the x and y dimensions extending along a width of the solar cell; and
a plurality of corresponding metal contacts formed at the end of the z-dimension of the three dimensional joints.

8. The solar cell according to claim 7, wherein a top surface of the solar cell has a layer of the conductive layer applied thereon and selective portions of the conductive layer being laser diffused across thickness of the solar cell in the form of a plurality of channels, the plurality of channels being disposed in spaced apart relationship with each other.

9. The solar cell according to claim 8, further including the conductive layer of second conductivity being disposed on a bottom surface of the solar cell, ends of each of the channels opening in the conductive layer and being exposed on the bottom surface.

10. The solar cell according to claim 7, wherein selective portions of the conductive substrate is heavily doped with a metallic material of the second conductivity to form heavily doped region therein.

11. The solar cell according to claim 10, wherein the metal contacts are disposed on each of the heavily doped region of the conductive substrate to form electrical connection with an external load.

12. The solar cell according to claim 7, further including a passivation layer formed at least on a top surface on the solar cell and on non-metallic portions on a bottom surface of the solar cell.
